(19) United States
(12) Patent Application Publication
(10) Pub. No.: US 2026/0334130 A1
(43) Pub. Date: Oct. 22, 2026

(54) SUBSTRATE PROCESSING METHOD, SUBSTRATE PROCESSING APPARATUS, AND RECORDING MEDIUM

(71) Applicant: Tokyo Electron Limited, Tokyo (JP)

(72) Inventors: Shoki MIZUGUCHI, Koshi City (JP); Hiroki SAKURAI, Koshi City (JP)

(73) Assignee: Tokyo Electron Limited, Tokyo (JP)

(21) Appl. No.: 19/529,149

(22) Filed: Feb. 4, 2026

(30) Foreign Application Priority Data
Feb. 5, 2025 (JP) 2025-017601

(51) Int. Cl. H10P 72/00; B05B 7/24; G03F 7/42; H10P 70/00

(52) U.S. Cl. CPC H10P 72/0414; B05B 7/24; G03F 7/422; H10P 70/20

(57) ABSTRACT

A substrate processing method includes discharging a processing liquid containing hydrofluoric acid onto a front surface of a substrate; discharging, after the discharging of the processing liquid, a rinse liquid onto the front surface of the substrate; and discharging, after the discharging of the rinse liquid, a mixed fluid of hydrogen peroxide solution and vapor or mist of pure water onto the front surface of the substrate.

### CROSS-REFERENCE TO RELATED APPLICATION

This application claims the benefit of Japanese Patent Application No. 2025-017601 filed on Feb. 5, 2025, the entire disclosures of which are incorporated herein by reference.

### TECHNICAL FIELD

The various aspects and embodiments described herein pertain generally to a substrate processing method, a substrate processing apparatus, and a recording medium.

### BACKGROUND

In a manufacturing process for a semiconductor device, there is known a technique of supplying SPM (Sulfuric acid Hydrogen Peroxide Mixture) to a substrate such as a semiconductor wafer to remove a target object such as a resist film from the substrate. Patent Document 1 discloses that the SPM is mixed with vapor of pure water before supplied to the substrate to improve processing efficiency.

Patent Document 1: Japanese Patent Laid-open Publication No. 2023-063227

### SUMMARY

In one exemplary embodiment, a substrate processing method includes discharging a processing liquid containing hydrofluoric acid onto a front surface of a substrate; discharging, after the discharging of the processing liquid, a rinse liquid onto the front surface of the substrate; and discharging, after the discharging of the rinse liquid, a mixed fluid of hydrogen peroxide solution and vapor or mist of pure water onto the front surface of the substrate.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1A is a schematic plan view illustrating an overall configuration of a substrate processing system as an exemplary embodiment of a substrate processing apparatus;

FIG. 1B is a schematic plan view illustrating an example configuration of a processing module incorporated in the substrate processing system of FIG. 1A;

FIG. 2 is a schematic side view illustrating the inside of the substrate processing system of FIG. 1A;

FIG. 3 is a cross sectional view illustrating a structure of a nozzle for SPM discharge, taken along a plane perpendicular to a lengthwise direction of the nozzle;

FIG. 4 is a cross sectional view of the nozzle taken along a line IV-IV in FIG. 3;

FIG. 5 is a cross sectional view of the nozzle taken along a line V-V in FIG. 3;

FIG. 6 is a schematic plan view of the nozzle shown in FIG. 3 to FIG. 5, seen from below;

FIG. 7 is a diagram illustrating an example of a piping system for supplying SPM and water vapor to the nozzle for SPM discharge;

FIG. 8A to FIG. 8C are schematic side views illustrating a flow of a series of processes performed on a single wafer in the exemplary embodiment;

FIG. 9A to FIG. 9D are schematic side views illustrating a flow of a series of processes performed on the single wafer in the exemplary embodiment;

FIG. 10A to FIG. 10D are schematic side views illustrating a flow of a series of processes performed on the single wafer in the exemplary embodiment; and

FIG. 11 is a graph showing an experiment result confirming the effect of mixing vapor into a hydrogen peroxide solution.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, embodiments for a substrate processing apparatus (substrate processing system) and a substrate processing method performed in the substrate processing apparatus according to the present disclosure (hereinafter, referred to as “exemplary embodiments”) will be described in detail with reference to the accompanying drawings. Further, it should be noted that the present disclosure is not limited by the exemplary embodiments. Furthermore, unless processing contents are contradictory, the various exemplary embodiments can be appropriately combined. In addition, in the various exemplary embodiments to be described below, same parts will be assigned same reference numerals, and redundant description will be omitted.

Further, in the following exemplary embodiments, expressions such as “constant,” “perpendicular,” “vertical” and “parallel” may be used. These expressions, however, do not imply strictly “constant”, “perpendicular,” “vertical” and “parallel”. That is, these expressions allow some errors and tolerances in, for example, manufacturing accuracy, installation accuracy, or the like.

Moreover, in the various accompanying drawings, for the purpose of clear understanding, there may be used a rectangular coordinate system in which the X-axis direction, Y-axis direction and Z-axis direction which are orthogonal to one another are defined and the positive Z-axis direction is defined as a vertically upward direction. Further, a rotational direction around a vertical axis may be referred to as “θ direction.”

<Overall configuration of Substrate Processing System>

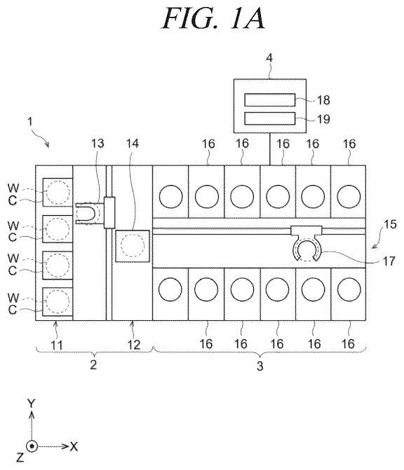

First, an overall schematic configuration of a substrate processing system 1 according to an exemplary embodiment of a substrate processing apparatus will be explained with reference to FIG. 1A. FIG. 1A is a diagram illustrating a schematic configuration of the substrate processing system 1 according to a first exemplary embodiment. In the following, in order to clarify positional relationships, the X-axis, Y-axis and Z-axis which are orthogonal to each other will be defined. The positive Z-axis direction will be regarded as a vertically upward direction.

As illustrated in FIG. 1A, the substrate processing system 1 (an example of the substrate processing apparatus) 1 is equipped with a carry-in/out station 2 and a processing station 3.

The carry-in/out station 2 is equipped with a carrier placement section 11 and a transfer section 12. In the carrier placement section 11, a plurality of carriers C (for example, FOUPs) is placed. Each carrier C accommodates a multiple number of substrates (semiconductor wafers W in the present exemplary embodiment) (hereinafter, for convenience's sake, simply referred to as “wafers W”) horizontally at equal intervals therebetween in a vertical direction.

The transfer section 12 is provided with a substrate transfer device 13 and a delivery module 14. The substrate transfer device 13 is a multi-axis transfer robot or a multi-joint transfer robot. The substrate transfer device 13 holds the wafer W with a fork-shaped wafer holder as an end effector, and transfers the wafer W between the carrier C and the delivery module 14.

The processing station 3 is equipped with a transfer section 15 and a plurality of processing modules 16.

A substrate transfer device 17 is provided inside the transfer section 15. The substrate transfer device 17 is a multi-axis transfer robot or a multi-joint transfer robot. The substrate transfer device 17 holds the wafer with a fork-shaped wafer holder as an end effector, and transfers the wafer W between the processing modules 16 and the delivery module 14.

The processing module 16 performs a liquid processing on the wafer W carried-in by the substrate transfer device 17 by supplying a processing fluid (SPM in the example to be described below).

The wafer W accommodated in the carrier C is taken out by the substrate transfer device 13 of the transfer section 12 and carried into the delivery module 14. The wafer W is then taken out by the substrate transfer device 17 of the transfer section 15, and is carried into the processing module 16. The wafer W processed in the processing module 16 is returned to its original carrier C via a route opposite to that described above.

The substrate processing system 1 is equipped with a control device 4 (illustrated only in FIG. 1A). The control device 4 is capable of controlling operations of all operable components included in the substrate processing system 1. The control device 4 is, for example, a computer, and includes a control processor 18 and a storage 19. The storage 19 stores a program (including a processing recipe that defines a processing sequence) that controls various processes performed in the substrate processing system 1. The control processor 18 controls the operation of the substrate processing system 1 by reading and executing the program stored in the storage 19. The control processor 18 may be a CPU (Central Processing Unit) or may be one or more circuits. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

The aforementioned program may have been stored on a computer-readable recording medium and installed from that recording medium into the storage 19 of the control device 4. The computer-readable recording medium may be, by way of non-limiting example, one of a hard disc (HD), a flexible disk (FD), a compact disk (CD), a magneto-optical disk (MO), a memory card, a random access memory (RAM), a read-only memory (ROM), and a solid-state drive (SSD), or a combination of two or more of these.

### <Configuration of Processing Module>

Now, an example configuration of the processing module 16 incorporated in the substrate processing system 1 will be described with reference to FIG. 1B. The processing module 16 includes a chamber 101, a substrate holder 102, a cup member 103, a first supply mechanism 140, a second supply mechanism 150, a third supply mechanism 160, a fourth supply mechanism 170, and a nozzle cleaning mechanism 106.

The substrate holder 102 includes a circular plate-shaped main body 121 larger than the wafer W in diameter, multiple grippers 122 provided on a peripheral portion of a top surface of the main body 121, a supporting column 123 supporting the main body 121, and a driver 124 for rotating the supporting column 123.

The substrate holder 102 holds the wafer W by gripping a peripheral portion of the wafer W by using the multiple grippers 122. At this time, the wafer W is held horizontally while being slighted apart from the top surface of the main body 121.

The cup member 103 is positioned to surround the substrate holder 102 and serves to receive a processing liquid scattered from the wafer W. A drain port 131 through which the processing liquid supplied to the wafer W is drained to the outside of the chamber 101 and an exhaust port 132 through which an atmosphere inside the chamber 101 is exhausted are provided at a bottom portion of the cup member 103.

The first supply mechanism 140, the second supply mechanism 150, and the third supply mechanism 160 supply a processing fluid required to process a top surface (front surface) of the wafer W.

The first supply mechanism 140 includes a first nozzle 141, a first arm 142 that supports the first nozzle 141, and a first pivoting/elevating mechanism 143 that pivots the first arm 142 and moves it up and down. The first pivoting/elevating mechanism 143 enables the first arm 142 to move the first nozzle 141 between a processing position above the wafer W (indicated by a dashed line in FIG. 1B) and a standby position outside the wafer W (indicated by a solid line in FIG. 1B).

The first nozzle 141 is formed as a bar nozzle having a length approximately equal to the radius of the wafer W. When the first nozzle 141 is located at the processing position, a leading end of the first nozzle 141 in its lengthwise direction is located above the center of the wafer W, and a basal end of the first nozzle 141 in its lengthwise direction is located above the peripheral portion of the wafer W.

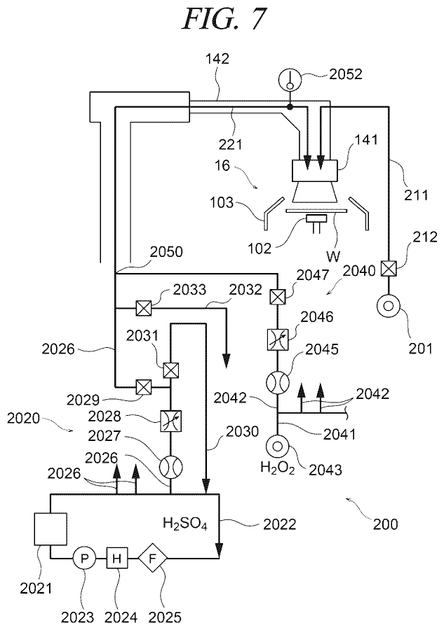

An example configuration of a processing fluid supply mechanism 200 for first nozzle, which is configured to supply the first nozzle 141 with a hydrogen peroxide solution, SPM (Sulfuric Acid Hydrogen Peroxide Mixture) (a chemical liquid in which sulfuric acid and hydrogen peroxide are mixed), and vapor as the processing fluid, will be explained below with reference to FIG. 7.

The processing fluid supply mechanism 200 includes a sulfuric acid supply 2020, a hydrogen peroxide solution supply 2040, a mixer 2050 that mixes the sulfuric acid and the hydrogen peroxide solution to produce the SPM, and a vapor supply 201.

The sulfuric acid supply 2020 includes a tank 2021 storing sulfuric acid, a circulation path 2022 connected to the tank 2021, and devices such as a pump 2023, a heater 2024, and a filter 2025 that are provided in the circulation path 2022. The tank 2021 is replenished with sulfuric acid as required from a sulfuric acid source (not shown) provided as a factory utility, for example. The pump 2023 forms a circulating flow of the sulfuric acid flowing from the tank 2021 into the circulation path 2022 and back into tank 2021. The sulfuric acid is circulated through the circulation path 2022 while being heated to a preset temperature (e.g., about 120 °C) by the heater 2024.

Branch supply lines (sulfuric acid supply lines to the respective processing modules 16) 2026 are branched off from the circulation path 2022. The number of these branch supply lines is the same as the number of the processing modules 16 provided in the substrate processing system 1, and each branch supply line 2026 is assigned to corresponding one chamber 101. Each branch supply line 2026 is equipped with a flow meter 2027, a flowrate control valve 2028, and an opening/closing valve 2029. A return line 2030 is branched off from the branch supply line 2026 between the flowrate control valve 2028 and the opening/closing valve 2029. The return line 2030 is provided with an opening/closing valve 2031.

The hydrogen peroxide solution supply 2040 has a main supply line 2041 connected to a hydrogen peroxide solution source 2043 that is provided as a factory utility, for example. Branch supply lines 2042 (hydrogen peroxide solution supply lines to the respective processing modules 16), the number of which is the same as the number of the processing modules 16, are branched off from the main supply line 2041, and each branch supply line 2042 is assigned to corresponding one processing module 16. Each branch supply line 2042 is equipped with a flow meter 2045, a flowrate control valve 2046, and an opening/closing valve 2047. A downstream end of the branch supply line 2042 of the hydrogen peroxide solution supply 2040 merges with the branch supply line 2026 for sulfuric acid. This merging portion serves as the mixer 2050 mentioned above. The branch supply line 2026 downstream of the mixer 2050 will also be referred to as “chemical liquid supply line 221.” A temperature sensor (temperature measurer) 2052 is provided at a downstream end of the chemical liquid supply line 221 (near a connection point with respect to the first nozzle 141). A structure for promoting the mixing of the sulfuric acid and the hydrogen peroxide solution, such as an in-line mixer, may be provided in the mixer 2050 or in the chemical liquid supply line 221 slightly downstream of the mixer 2050.

A drain line 2032 is branched off from the branch supply line 2026 for sulfuric acid between the mixer 2050 and the opening/closing valve 2029. The drain line 2032 is provided with an opening/closing valve 2033. This drain line 2032 may be used to drain the SPM remaining in the chemical liquid supply line 221 after a processing of one wafer W is completed and before a processing of a next wafer W is started, for example.

As can be clearly seen from a piping system of FIG. 7, by supplying only the hydrogen peroxide solution to the mixer 2050 without supplying sulfuric acid, the hydrogen peroxide solution without containing sulfuric acid can be supplied to the first nozzle 141. Furthermore, by supplying both sulfuric acid and hydrogen peroxide solution to the mixer 2050, the SPM can be supplied to the first nozzle 141.

The vapor supply 201 is equipped with a vapor generator or mist generator, and is capable of supplying a fluid including vapor or mist of pressurized DIW (pure water) (hereinafter also referred to as “vapor” for simplicity of description) to the first nozzle 141 via a supply line 211 that is provided with an opening/closing valve 212.

The second supply mechanism 150 includes three nozzles 151A, 151B, and 151C (collectively referred to as “second nozzles”), a second arm 152 that supports and moves the second nozzles 151A, 151B, and 151C, and a second pivoting/elevating mechanism 153 that pivots the second arm 152 and also moves it up and down. The second arm 152 is capable of moving the second nozzles 151A, 151B, and 151C between a home position (standby position) outside the periphery of the wafer W and a processing position above the wafer W. The second nozzle 151A supplies an inert gas, such as nitrogen (N₂) gas, onto the front surface of the wafer W. The second nozzle 151B supplies a replacement liquid, such as IPA (isopropyl alcohol), onto the front surface of the wafer W. The second nozzle 151C selectively supplies either DHF (dilute hydrofluoric acid) or room-temperature DIW onto the front surface of the wafer W.

The third supply mechanism 160 includes two nozzles 161A and 161B (collectively referred to as “third nozzles”), a third arm 162 that supports and moves the third nozzles 161A and 161B, and a third pivoting/elevating mechanism 163 that pivots the third arm 162 and also moves it up and down. The third arm 162 is capable of moving the third nozzles 161A and 161B between a home position (standby position) outside the periphery of the wafer W and a processing position above the wafer W. The third nozzle 161A selectively supplies one of SC1 (a mixed solution of ammonia water, hydrogen peroxide, and water), a hydrogen peroxide solution, heated DIW (HDIW), and room-temperature DIW onto the front surface of the wafer W. The third nozzle 161B supplies a two-fluid mixture, which is a fluid mixture of atomized DIW and an inert gas (e.g., a nitrogen gas), onto the wafer W.

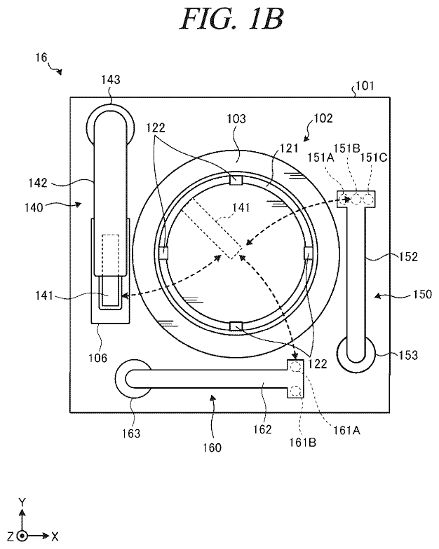

The fourth supply mechanism 170 supplies a processing fluid required for a processing to a bottom surface (rear surface) of the wafer W. As schematically shown in FIG. 2, the fourth supply mechanism 170 has three nozzles 171A, 171B, and 171C (collectively referred to as “fourth nozzles”). In one example configuration, the supporting column 123 of the substrate holder 102 is hollow, with a thin, elongated cylindrical member inserted in this hollow portion. The cylindrical member has multiple fluid passages extending vertically. Each of the fluid passages has an opening end opened toward the approximate center of the bottom surface of the wafer W, and these opening ends serve as the fourth nozzles 171A, 171B, and 171C. The fourth nozzle 171A selectively discharges either DHF or room-temperature DIW. The fourth nozzle 171B discharges HDIW (heated DIW). The fourth nozzle 171C discharges an inert gas (here, a nitrogen gas (also referred to as N₂ gas)).

Although not shown, the respective nozzles of the second supply mechanism 150, the third supply mechanism 160, and the fourth supply mechanism 170 are connected to supply sources of processing fluids (chemical liquids such as sulfuric acid and a hydrogen peroxide solution, DIW, an inert gas, etc.) via supply lines (pipelines). These processing fluid sources may be provided as a factory utility or may be storages storing the processing fluids, such as tanks or cylinders. Each supply line is provided with a flow control device, including an opening/closing valve, a flowrate control valve, a flow meter, and the like, so that the processing fluid can be supplied to the corresponding nozzle at a controlled flow rate via the supply line. Multiple supply lines, each equipped with a flow control device, are connected to a nozzle configured to discharge multiple types of processing fluids, such as the third nozzle 161A, and a switching valve device (for example, composed of multiple opening/closing valves) allows one of these multiple supply lines to be connected to that nozzle. In the case of a two-fluid nozzle such as the third nozzle 161B, a liquid supply line and a gas supply line are connected to this nozzle, and a flow control device is provided in each of these lines. Since the configuration of the supply sources and the supply lines of the second supply mechanism 150, the third supply mechanism 160, and the fourth supply mechanism 170 are well known in the field of semiconductor manufacturing technology, further detailed explanation will be omitted here.

The nozzle cleaning mechanism 106 is provided at the standby position of the first nozzle 141. The nozzle cleaning mechanism 106 cleans the first nozzle 141.

### <Configuration of First Nozzle>

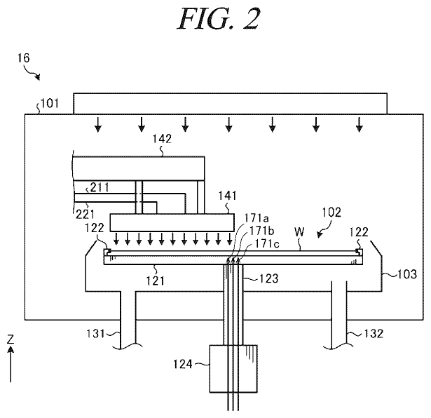

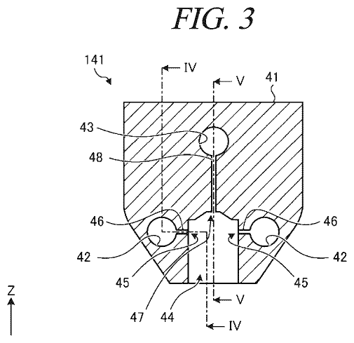

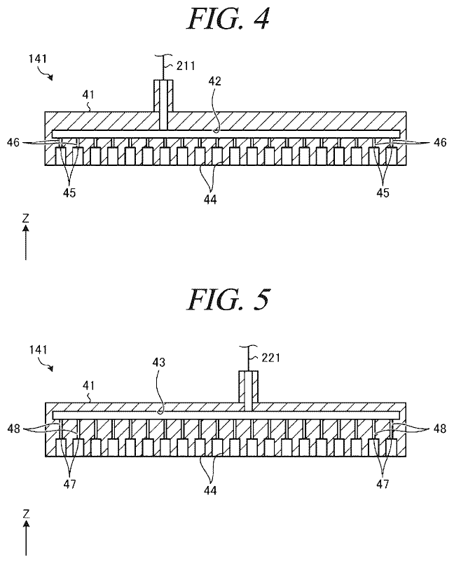

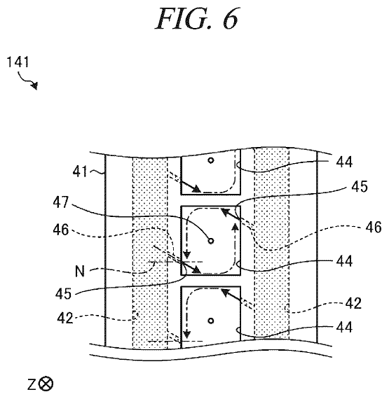

Now, the configuration of the first nozzle 141 will be explained in detail with reference to FIG. 3 to FIG. 6. FIG. 3 is a cross sectional view of the first nozzle 141 according to one configuration example, taken along a plane perpendicular to the lengthwise direction of the first nozzle 141. Further, FIG. 4 is a cross sectional view taken along a line IV-IV, seen from the direction indicated by arrows in FIG. 3. FIG. 5 is a cross sectional view taken along a line V-V, seen from the direction indicated by arrows in FIG. 3. FIG. 6 is a schematic plan view of the first nozzle 141 according to a first exemplary embodiment, seen from below. In FIG. 6, regions in which vapor flows is indicated by dots.

As shown in FIG. 3, the first nozzle 141 includes a nozzle main body 41, two first distribution paths 42, one second distribution path 43, and multiple outlet paths 44 (see FIG. 4 and FIG. 5). Further, the first nozzle 141 also includes multiple first discharge openings 45, multiple first discharge paths 46 (see FIG. 4), multiple second discharge openings 47, and multiple second discharge paths 48 (see FIG. 5).

The first distribution path 42 and the second distribution path 43 are formed inside the nozzle main body 41. As illustrated in FIG. 4 and FIG. 5, the first distribution path 42 and the second distribution path 43 extend along the lengthwise direction of the nozzle main body 41. The first distribution path 42 is connected to the vapor supply 201 via the vapor supply line 211. The second distribution path 43 is connected to the chemical liquid supply line 221.

As shown in FIG. 3, the second distribution path 43 is located on the centerline of the nozzle main body 41 (the line that bisects the nozzle main body 41 into left and right halves) in a cross sectional view thereof. Further, the two first distribution paths 42 are located on the left and right sides of the centerline of the nozzle main body 41 in the cross sectional view thereof.

The multiple outlet paths 44 are located below the second distribution path 43. As shown in FIG. 3 to FIG. 5, the multiple outlet paths 44 are flow paths provided in a lower portion of the nozzle main body 41, and they extend vertically downwards. For example, the multiple outlet paths 44 are arranged at equal intervals therebetween along the lengthwise direction of the nozzle main body 41. The neighboring outlet paths 44 are separated by partitions. The cross sectional shape of each outlet path 44 is, by way of example, rectangular. The cross sectional shape of the outlet path 44 may also be circular, elliptical, or the like.

The first discharge opening 45 is opened to an inner side surface of the outlet path 44. The second discharge opening 47 is located higher than the first discharge opening 45 and is opened to an upper end surface of the outlet path 44. As shown in FIG. 4 and FIG. 5, the multiple first discharge openings 45 and the multiple second discharge openings 47 are arranged at equal intervals therebetween along the lengthwise direction of the nozzle main body 141. The first discharge openings 45 and the second discharge openings 47 are arranged so as to be aligned in a radial direction of the wafer W below the first nozzle 141 when the first nozzle 141 is located at the processing position.

As depicted in FIG. 3 to FIG. 6, the first nozzle 141 has the multiple first discharge openings 45 and the multiple second discharge openings 47 as well as the multiple outlet paths 44 each communicating with two of the first discharge openings 45 and one of the second discharge openings 47. Here, the number of the first discharge openings 45 and the number of the second discharge openings 47 communicating with the one outlet path 44 is not limited to those shown in FIG. 3 to FIG. 6. That is, the first nozzle 141 may have multiple outlet paths 44 each communicating with at least one first discharge opening 45 and at least one second discharge opening 47.

The multiple first discharge openings 45 are connected to the first distribution path 42 via the multiple first discharge paths 46. Furthermore, the multiple second discharge openings 47 are connected to the second distribution path 43 via the multiple second discharge paths 48.

The vapor supplied from the vapor supply 201 to the first distribution path 42 is distributed from the first distribution path 42 into the multiple first discharge paths 46 and then discharged from the multiple first discharge openings 45 into the multiple outlet paths 44 respectively corresponding thereto. Further, the chemical liquid (hydrogen peroxide or SPM) supplied from the chemical liquid supply line 221 to the second distribution path 43 is distributed from the second distribution path 43 into the multiple second discharge paths 48 and discharged from the multiple second discharge openings 47 into the multiple outlet paths 44 respectively corresponding thereto.

The vapor discharged from the first discharge opening 45 and the chemical liquid discharged from the second discharge opening 47 are mixed near an upper end as an inlet of the corresponding outlet path 44, and then discharged toward the wafer W from a lower end as an outlet of the outlet path 44.

As shown in FIG. 6, the second discharge opening 47 is disposed coaxially with respect to the outlet path 44 in a plan view. The second discharge opening 47 discharges a chemical liquid in a direction along the central axis of the outlet path 44 (i.e., the Z-axis direction). The first discharge opening 45 is disposed toward a position offset from the central axis of the outlet path 44 in a plan view. The first discharge opening 45 discharges the vapor toward the position offset from the central axis of the outlet path 44 in a plan view. As a result, the vapor that has collided with the inner side surface of the outlet path 44 forms a swirling flow in the outlet path 44 and is mixed with the chemical liquid discharged from the second discharge opening 47. To form such a swirling flow of the vapor in the outlet path 44, the vapor discharged from the first discharge opening 45 simply needs to flow along the inner side surface of the outlet path 44.

The first nozzle 141 having the shown configuration allows the vapor and the chemical liquid to be efficiently mixed and the temperature of the chemical liquid to be efficiently increased.

Furthermore, as shown in FIG. 6, the central axis of the first discharge opening 45 is inclined with respect to the direction of a normal line N of the inner side surface of the outlet path 44 in a plan view. By inclining the central axis of the first discharge opening 45 with respect to the direction of the normal line N, it is easier to form the swirling flow of the vapor in the outlet path 44, as compared to when the central axis of the first discharge opening 45 is perpendicular to the inner side surface of the outlet path 44. Furthermore, the swirling flow may lengthen the time during which the vapor stays in the outlet path 44, thereby reducing the amount of the vapor used to mix the vapor and the chemical liquid.

The configuration of the first nozzle 141 is desirably as shown in FIG. 3 to FIG. 6, but is not limited thereto. As long as the vapor and the chemical liquid can be mixed in the first nozzle 141 in a substantially uniform manner and then the mixed fluid of the vapor and the chemical liquid can be discharged from the first nozzle 141 onto the wafer W, the configuration of the first nozzle 141 is not particularly limited.

As is clear from the piping system in FIG. 7, by supplying only the hydrogen peroxide solution to the mixer 2050 without supplying sulfuric acid, the hydrogen peroxide without containing sulfuric acid is supplied to the first nozzle 141 as the chemical liquid. Furthermore, by supplying both the sulfuric acid and the hydrogen peroxide solution to the mixer 2050, the SPM, which is the mixed chemical liquid of the sulfuric acid and the hydrogen peroxide solution, is supplied to the first nozzle 141.

A nozzle known in the technical field of semiconductor manufacturing apparatus may be used as a nozzle other than first nozzle 141. Illustration and description of the structure of such a known nozzle will be omitted here.

### <Processing Performed in Processing Module>

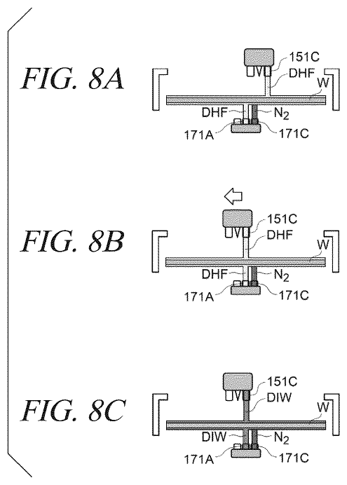

Now, a processing performed on a wafer in the processing module 16 will be explained with reference to schematic side views of FIG. 8A to FIG. 10D. The processing described below is also performed under the control of the control device 4 shown in FIG. 1A.

### <Carry-In Process>

First, a carry-in processing of the wafer W is performed. Specifically, the substrate transfer device 17 of the transfer section 15 carries the wafer W into the processing module 16, where the wafer W is held by the substrate holder 102. The wafer W as a processing target has, for example, an oxide or a nitride film formed on its front surface, and a material to be removed from the front surface of the wafer W through a series of processes is an organic material such as a resist residue as well as an abrasive.

Then, the substrate holder 102 begins to be rotated at a preset rotation speed. This rotation of the wafer W continues until the series of processes are completed for the single wafer W (the rotation speed may be appropriately changed as required). Further, unless otherwise mentioned, a small amount of N₂ gas is constantly discharged from the fourth nozzle 171C when a liquid is being supplied to the rear surface (bottom surface) of the wafer W.

### <Native Oxide Film Removing Process>

As shown in FIG. 8A, the second nozzle 151C is positioned directly above a central portion of the wafer W being rotated, and DHF is discharged from the second nozzle 151C onto the center of the wafer W.

The DHF is made to flow toward the periphery of the wafer W and scatter outwards from the wafer by a centrifugal force. As a result, the entire front surface of the wafer W is covered with a liquid film of the DHF. The supplied DHF removes a native oxide film that has been formed on the surface of the wafer W. It is desirable to locate the second nozzle 151C directly above a position offset radially outwards from the rotation center of the wafer W (but the position where the entire front surface of the wafer W is ensured to be covered with the DHF). With this configuration, the rotation center of the wafer W can be suppressed from being locally etched significantly.

While heated DHF is being supplied to the front surface of the wafer W, DHF is discharged from the fourth nozzle 171A toward a central portion of the rear surface of the wafer W. This DHF also flows outwards on the wafer W, covering the entire rear surface of the wafer W, thereby removing a native oxide film that has been formed on the rear surface of the wafer W.

The chemical liquid used in the native oxide film removing process is, by way of example, DHF with a concentration of approximately 1%, but a hydrofluoric acid-containing processing liquid, such as BHF, may also be used.

### <Rinsing Process (Post-DHF Rinsing Process)>

At the end of the native oxide film removing process, the second nozzle 151C, which is discharging the DHF, is located above the center of the wafer W (see FIG. 8B). Then, the processing fluid discharged from the second nozzle 151C and the fourth nozzle 171A is switched from the DHF to DIW (see FIG. 8C), proceeding to a rinsing process. The discharge of the DIW from the fourth nozzle 171A may continue throughout the rinsing process, or may also be stopped for several seconds during the rinsing process.

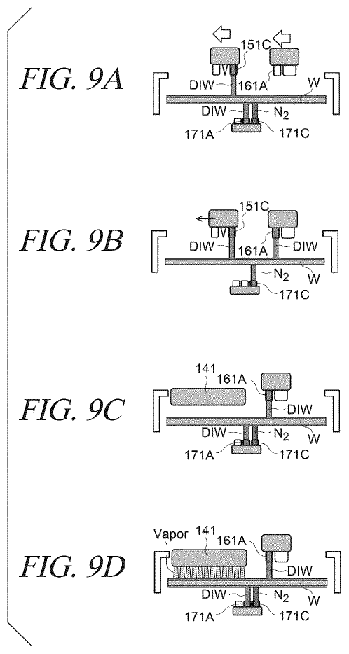

Next, the second nozzle 151C discharging the DIW is moved to a position directly above a position offset radially outwards from the rotation center of the wafer W, and the third nozzle 161A is moved to a position directly above a position offset radially outwards from the rotation center of the wafer W on the opposite side from the second nozzle 151C (see FIG. 9A). The second nozzle 151C and the third nozzle 161A are located at the positions where the entire front surface of the wafer W is ensured to be covered with the DIW. Here, this switching of the nozzles discharging the DIW is not necessarily required if there is no interference between the arms or nozzles during a subsequent process.

Next, the second nozzle 151C, which is discharging the DIW, is moved toward the home position (standby position) (as indicted by an arrow in FIG. 9B). When the second nozzle 151C is moved outside the periphery of the wafer W in a plan view, the discharge of the DIW from the second nozzle 151C is stopped. Concurrently with this movement of the second nozzle 151C, the third nozzle 161A, which is discharging the DIW, is moved to a position directly above a position offset radially outwards from the rotation center of the wafer W and stopped thereat. The position of the third nozzle 161A at this time is a position where the third nozzle 161A is ensured not to interfere with the first nozzle 141 when the first nozzle 141 is later located at the processing position above the wafer W, and is also a position as close to the rotation center of the wafer W as possible, where the entire wafer W is covered with a liquid film of the DIW.

Subsequently, while continuing the discharge of the DIW from the third nozzle 161A, the first nozzle 141 is located at the processing position (see FIG. 9C). Thereafter, only vapor (including neither sulfuric acid nor hydrogen peroxide) is discharged from the first nozzle 141 (see FIG. 9D). The discharge of the vapor from the first nozzle 141 is carried out by opening the opening/closing valve 212 shown in FIG. 7.

This discharge of the vapor from the first nozzle 141 is not intended to enhance a rinsing effect, but is performed to discharge water (DIW) condensed in the first nozzle 141 and the pipeline connected thereto. The discharge of the vapor from the first nozzle 141 can also be regarded as dummy dispense from the first nozzle 141 onto the wafer W. If the condensed water drips as droplets when mist and a reactive chemical liquid (hydrogen peroxide, SPM, etc.) are later discharged from the first nozzle 141, there is a risk that an undesirable reaction may occur. If, however, the vapor is discharged from the first nozzle 141 during the rinsing process, when the entire front surface of the wafer W is covered with the liquid film of water (DIW), the water droplets falling onto the wafer W do not cause a problem. Although the water droplets may contain a particle-generating substance, they are immediately removed from the front surface of the wafer W after falling onto the liquid film of the DIW, so there is no risk of contamination of the wafer W.

The discharge of only the vapor from the first nozzle 141 without accompanying discharge of a hydrogen peroxide solution needs to be performed for as much as the time required to fully drain the condensed water from the first nozzle 141 and the pipeline connected thereto, for example, 1 second to 5 seconds.

### <Ooxide Film Formation Process>

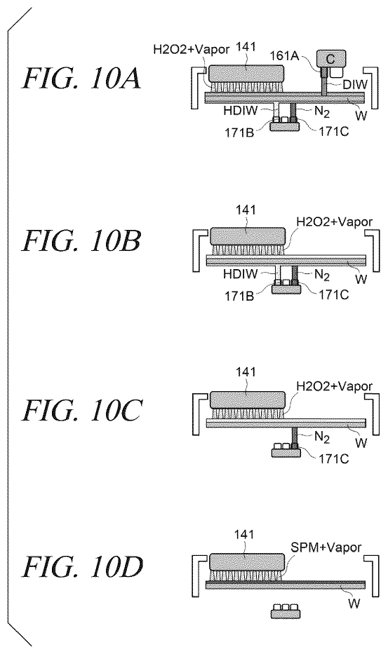

Next, while continuing the discharge of the DIW from the third nozzle 161A and also continuing the discharge of the vapor from the first nozzle 141, a hydrogen peroxide solution is supplied to the first nozzle 141 (without supplying sulfuric acid) (see FIG. 10A). The supply of the hydrogen peroxide solution to the first nozzle 141 is carried out by opening the opening/closing valve 2047 shown in FIG. 7. The hydrogen peroxide is mixed with the vapor in the first nozzle 141 and then discharged onto the wafer W as a mixed fluid in the form of mist. The mixed fluid falls onto the liquid film of the DIW covering the entire wafer W to be mixed with the DIW, flows on the wafer W, and then flows off the wafer W.

At approximately the same time as the start of the supply of the hydrogen peroxide solution to the first nozzle 141, the discharge of the DIW from the fourth nozzle 171A is stopped, and the discharge of HDIW heated to, for example, about 70 °C to 80 °C is started from the fourth nozzle 171B (see FIG. 10B). This raises the temperature of the wafer W, accelerating an oxidation reaction of the front surface of the wafer W by the hydrogen peroxide solution. The time during which the discharge of the hydrogen peroxide solution and the vapor from the first nozzle 141 and the discharge of the DIW from the fourth nozzle 171A simultaneously may be, for example, approximately 5 seconds to 15 seconds.

Next, the third nozzle 161A, which is discharging the DIW, is moved toward the home position (standby position) (scan-out of the third nozzle 161A). At this time, the third nozzle 161A may be stopped temporarily at a position directly above a position radially offset outwards from the rotation center of the wafer W (for example, a position offset by about two-thirds of the radius of the wafer W), and then scanned out.

When the third nozzle 161A is located outside the periphery of the wafer W in a plan view, the discharge of the DIW from the third nozzle 161A is stopped (see FIG. 10C). This results in a state in which only the mixed fluid of the hydrogen peroxide solution and the vapor is supplied on the front surface of the wafer W from the first nozzle 141. This state is maintained for a preset time (e.g., approximately 50 seconds to 100 seconds). As a result, a chemical oxide film is uniformly formed on the entire front surface of the wafer W. Here, the term “chemical oxide film” refers to an oxide film formed by using an oxidizing chemical liquid, and in this respect, it differs from the “native oxide film.”

The chemical oxide film formed by using the chemical liquid is more uniform than the native oxide film and has uniform hydrophilic property. Furthermore, as stated above, by first supplying the DIW and the mixed fluid of the hydrogen peroxide solution and the vapor, and later supplying only the mixed fluid of the hydrogen peroxide solution and the vapor without supplying the DIW, it is possible to form the chemical oxide film in an even manner without causing non-uniformity in the processing. On the front surface of the wafer W, which has become hydrophilic and on which the chemical oxide film has been uniformly formed, SPM easily permeates (that is, wettability of the SPM is high). This allows a reaction between the SPM and the target material to be removed to be started rapidly, thereby shortening a processing time. Furthermore, since uneven wetting of the SPM does not occur, the SPM treatment can be performed with high in-surface uniformity, and particle generation due to the uneven wetting may be suppressed.

By discharging the hydrogen peroxide solution onto the wafer W in the form of the mixed fluid with the vapor, the temperature of the hydrogen peroxide solution increases, enhancing its oxidizing ability. Therefore, the chemical oxide film of a sufficient thickness can be formed in a short period of time.

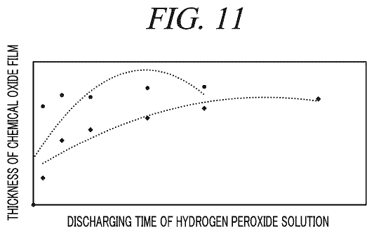

An example of an experimental result confirming the effect of mixing the vapor with the hydrogen peroxide solution in the oxide film formation process will be explained below with reference to FIG. 11. A test has been conducted by using the processing module 16 with a configuration corresponding to that shown in FIG. 1A. A bare silicon wafer with a native oxide film formed on a front surface thereof is prepared, and is subjected to the native oxide film removing process, the rinsing process, and the oxide film formation process described above, followed by rinsing with pure water and scattering drying (experimental example). As a comparative example, a processing different from the experimental example only in that no vapor is mixed with the hydrogen peroxide solution in the oxide film formation process is performed on a bare silicon wafer. Thicknesses of chemical oxide films formed on the front surfaces of the wafers are measured for both the experimental example and the comparative example. In the native film removing process, room-temperature DHF with a concentration of 1% is used. In the oxide film formation process, room-temperature hydrogen peroxide solution is used.

FIG. 11 shows a relationship between a processing time of the oxide film formation process (discharging time of the hydrogen peroxide solution) and a thickness of the chemical oxide film formed on the front surface of the wafer W. When the vapor is mixed with the hydrogen peroxide solution (plotted with ●), the chemical oxide film is found to be formed to have a sufficient thickness in less than one-third the time taken when no vapor is mixed (plotted with ▪).

### <SPM Treatment Process>

Next, the rotation speed of the wafer W is slowed, and sulfuric acid is supplied to the first nozzle 141, from which the mixed solution of the hydrogen peroxide solution and the vapor is being discharged. As a result, a mixed solution of SPM and the vapor (SPM+Vapor) is discharged from the first nozzle 141 onto the front surface of the wafer W (see FIG. 10D), and the hydrogen peroxide solution covering the front surface of the wafer W is replaced with the SPM. This SPM removes the target material to be removed adhering to the front surface of the wafer W. As is known in the art, by mixing the vapor and the SPM, the reactivity between the SPM and the front surface of the wafer W is improved, thereby accelerating etching.

The reason for reducing the rotation speed of the wafer W before the discharge of the SPM from the first nozzle 141 is begun (that is, before the sulfuric acid begins to be mixed) is to minimize SPM droplets scattering to the outside of the cup member 103 and thus suppress contamination of the interior of the chamber 16. After the SPM treatment process is begun, the discharge of the HDIW from the fourth nozzle 171B is stopped.

Specifically, the transition from the oxide film formation process to the SPM treatment process is performed as follows. That is, with the opening/closing valve 2047 opened and the hydrogen peroxide solution being supplied to the first nozzle 141 via the branch supply line 2026, the mixer 2050, and the chemical liquid supply line 221, the opening/closing valve 2029 is also opened. As a result, the sulfuric acid is introduced from the branch supply line 2026 into the mixer 2050, where the sulfuric acid and the hydrogen peroxide solution are mixed to produce the SPM, and this SPM is then supplied to the first nozzle 141 through the chemical liquid supply line 221.

The supply flow rate of the hydrogen peroxide solution may be changed before and after the operation of opening the opening/closing valve 2029.

In the transition from the oxide film formation process to the SPM treatment process, the chemical liquid (processing fluid) supplied to the first nozzle 141 from the chemical liquid supply line 221 is switched from the hydrogen peroxide solution to the SPM while the supply of the vapor to the first nozzle 141 is carried on. As the supply of the vapor to the first nozzle 141 is not stopped and the supply of the hydrogen peroxide solution to the first nozzle 141 is not stopped either, the switching of the processing fluid supplied to the first nozzle 141 is carried out without being interrupted.

By not stopping or suspending the supply of the processing fluid to the first nozzle 141, or by minimizing it as much as possible, occurrence of stoppage or stagnation of the fluid inside the first nozzle 141 and the pipelines connected thereto is minimized. Accordingly, the state of the fluid being supplied to the first nozzle 141 may be stabilized, and a high level of cleanliness may be maintained. Furthermore, the frequency of the valve opening and closing operations can be minimized, so that particle generation accompanying these valve opening and closing operations may be suppressed. Therefore, a high-quality processing is enabled.

Furthermore, during the above-described series of processes (post-DHF rinsing process→oxide film formation process→SPM treatment process), the liquid film of the DIW→the liquid film of the mixed solution of the DIW and the hydrogen peroxide solution→the liquid film of the hydrogen peroxide solution→the liquid film of the SPM are formed on the front surface of the wafer W in this order. There is no problem even if the hydrogen peroxide solution falls onto the liquid film of the DIW, and there is no problem even if the SPM falls onto the liquid film of the hydrogen peroxide solution. In other words, according to the above-described series of processes, transition between the liquid films present on the front surface of the wafer W can be carried out smoothly.

Assume a procedure in which the SPM falls onto the liquid film of the DIW (for example, oxide film formation→DIW rinsing→SPM treatment). In this case, when the SPM falls onto the liquid film of the DIW, local sudden bumping may occur, which in turn could cause contamination of the inside of the processing module or generation of particle-causing substances. Therefore, when the SPM treatment is performed after the DIW treatment, it is necessary to, for example, shake off the DIW from the wafer W and then supply the SPM onto the wafer W. However, this increases the processing time per wafer. Furthermore, drying the front surface of the wafer W during the series of processes is undesirable from the viewpoint of prevention of particle generation, etc. However, in the above-described sequence of the series of processes according to the exemplary embodiment, such problems do not arise.

### <Rinsing Process (Post-SPM Rinsing Process)>

After performing the SPM treatment process for a preset period of time, the third nozzle 161A is positioned slightly apart from the rotation center of the wafer, and the discharge of the mixed fluid of the SPM and the vapor from the first nozzle 141 is stopped in this state. Subsequently, the rotation speed of the wafer W is increased, and DIW is discharged from the third nozzle 161A as a rinse liquid to perform a rinsing process. During this process, the DIW falls onto the liquid film of the SPM. However, since the wafer W is being rotated, the liquid film of the SPM is thin, so even if the DIW falls onto it, there arises no problem due to the mixing of the SPM and the DIW.

The rinse liquid supplied to the wafer W flows while being diffused toward the periphery of the wafer W due to a centrifugal force generated by the rotation of the wafer W, and is then scattered outside the wafer W. As a result, the SPM remaining on the wafer W is washed away by the rinse liquid. During the rinsing process, the landing position of the rinse liquid may be moved between a central portion and a peripheral portion of the wafer. The first nozzle 141, which has stopped discharging the mixed fluid, is returned to its home position (standby position) and cleaned by the nozzle cleaning mechanism 106. A two-fluid rinsing process may be performed prior to this rinsing process.

### <Replacement Process>

Next, a replacement liquid (IPA) is supplied to the central portion of the front surface of the wafer W from the second nozzle 151B for replacement liquid supply. The replacement liquid supplied to the wafer W flows while being diffused toward the periphery of the wafer W due to a centrifugal force caused by the rotation of the wafer W, thereby replacing the rinse liquid remaining on the wafer W with the replacement liquid.

### <Drying Process>

Thereafter, with the discharge of the replacement liquid from the second nozzle 151B stopped, the rotation speed of the wafer W is increased. This allows the replacement liquid remaining on the wafer W to be shaken off, thereby drying the wafer W. Thereafter, the rotation of the wafer W is stopped.

The replacement process and the drying process may be performed simultaneously. Specifically, for example, a nitrogen gas may be discharged from the second nozzle 151A and IPA may be discharged from the second nozzle 151B, and the second nozzles 151A and 151B may be moved radially outwards so that the second nozzle 151A discharging the nitrogen gas is positioned radially inward of the second nozzle 151B discharging the IPA.

### <Carry-Out Process>

Next, a carry-out processing is performed. In the carry-out processing, the substrate transfer device 17 of the transfer section 15 carries out the wafer W held by the substrate holder 102 out of the processing module 16. This completes the series of processes performed on the single wafer W in the processing module 16.

Further, after the above-described rinsing process, the replacement process and the drying process may be performed after conducting a required chemical liquid treatment (for example, a SC1 treatment, a SC2 treatment, etc.) and a rinsing process.

It should be noted that the above-described exemplary embodiment is illustrative in all aspects and is not anyway limiting. The above-described exemplary embodiment may be omitted, replaced and modified in various ways without departing from the scope and the spirit of claims.

The substrate as a processing target is not limited to the semiconductor wafer, but may be any of various types of substrates used in the technical field of semiconductor device manufacturing, such as a glass substrate, a ceramic substrate, and the like.

According to the exemplary embodiment, it is possible to reduce the substrate processing time. From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

We claim

1. A substrate processing method, comprising:
discharging a processing liquid containing hydrofluoric acid onto a front surface of a substrate;
discharging, after the discharging of the processing liquid, a rinse liquid onto the front surface of the substrate; and
discharging, after the discharging of the rinse liquid, a mixed fluid of hydrogen peroxide solution and vapor or mist of pure water onto the front surface of the substrate.

2. The substrate processing method of claim 1,
wherein the rinse liquid used in the discharging of the rinse liquid is water.

3. The substrate processing method of claim 1, further comprising:
supplying a heated temperature control fluid to a rear surface of the substrate during the discharging of the mixed fluid of the hydrogen peroxide solution and vapor or mist of pure water to heat the substrate.

4. The substrate processing method of claim 3,
wherein the temperature control fluid is heated water.

5. The substrate processing method of claim 1,
wherein the discharging of the mixed fluid of the hydrogen peroxide solution and vapor or mist of pure water is started before the discharging of the rinse liquid is completed, and when the discharging of the mixed fluid of the hydrogen peroxide solution and vapor or mist of pure water is started, a landing point of the rinse liquid being supplied onto the front surface of the substrate in the discharging of the rinse liquid is moved toward a periphery of the substrate and then away from the substrate.

6. The substrate processing method of claim 1, further comprising:
discharging, after the discharging of the mixed fluid of the hydrogen peroxide solution and vapor or mist of pure water, a mixed fluid of a sulfuric acid hydrogen peroxide mixture (SPM), which is a mixture of sulfuric acid and hydrogen peroxide solution, and vapor or mist of pure water onto the front surface of the substrate.

7. The substrate processing method of claim 6,
wherein the discharge of the mixed fluid of the hydrogen peroxide solution and the vapor or mist of the pure water in the discharging of the mixed fluid of the hydrogen peroxide solution and vapor or mist of pure water and the discharge of the mixed fluid of the SPM and the vapor or mist of the pure water in the discharging of the mixed fluid of the SPM and vapor or mist of pure water are performed by using a same mixed fluid nozzle.

8. The substrate processing method of claim 7,
wherein the mixed fluid nozzle used in the discharging of the mixed fluid of the hydrogen peroxide solution and vapor or mist of pure water and the discharging of the mixed fluid of the SPM and vapor or mist of pure water is a bar nozzle having multiple discharge openings, and when a lengthwise direction of the bar nozzle is aligned with a radial direction of the substrate, the multiple discharge openings are arranged in the radial direction of the substrate.

9. The substrate processing method of claim 7,
wherein a nozzle discharging the rinse liquid in the discharging of the rinse liquid is different from the mixed fluid nozzle used in the discharging of the mixed fluid of the hydrogen peroxide solution and vapor or mist of pure water and the discharging of the mixed fluid of the SPM and vapor or mist of pure water.

10. The substrate processing method of claim 7,
wherein the transition from the discharging of the mixed fluid of the hydrogen peroxide solution and vapor or mist of pure water to the discharging of the mixed fluid of the SPM and vapor or mist of pure water is carried out by switching a processing liquid supplied to the mixed fluid nozzle from the hydrogen peroxide solution to the SPM while continuing the supply of the vapor or mist of the pure water to the mixed fluid nozzle.

11. The substrate processing method of claim 10,
wherein the switching of the processing liquid supplied to the mixed fluid nozzle from the hydrogen peroxide solution to the SPM is carried out by merging a flow of sulfuric acid into a flow of the hydrogen peroxide solution heading toward the mixed fluid nozzle without interrupting the flow of the hydrogen peroxide solution.

12. The substrate processing method of claim 6,
wherein a rotation speed of the substrate is reduced at an end of the discharging of the mixed fluid of the hydrogen peroxide solution and vapor or mist of pure water, and then the transition from the discharging of the mixed fluid of the hydrogen peroxide solution and vapor or mist of pure water to the discharging of the mixed fluid of the SPM and vapor or mist of pure water is performed.

13. A substrate processing apparatus, comprising:
a substrate holder holding a substrate;
a hydrofluoric acid-containing processing liquid supply supplying a processing liquid containing hydrofluoric acid onto a front surface of the substrate;
a rinse liquid supply supplying a rinse liquid onto the front surface of the substrate;
a mixed fluid nozzle supplying, onto the front surface of the substrate, either one of a fluid containing vapor or mist of pure water or a hydrogen peroxide solution individually or both simultaneously;
a pure water vapor supply supplying the fluid containing the vapor or mist of the pure water to the mixed fluid nozzle;
a hydrogen peroxide solution supply supplying the hydrogen peroxide solution to the mixed fluid nozzle; and
control circuitry configured to control an operation of the substrate processing apparatus to perform:
a first process of discharging the processing liquid containing the hydrofluoric acid onto the front surface of the substrate, using the hydrofluoric acid-containing processing liquid supply;
a second process of discharging, after the first process, the rinse liquid onto the front surface of the substrate, using the rinse liquid supply; and
a third process of discharging, after the second process, the mixed fluid of the hydrogen peroxide solution and the vapor or mist of the pure water onto the front surface of the substrate, using the mixed fluid nozzle, the pure water vapor supply and the hydrogen peroxide solution supply.

14. The substrate processing apparatus of claim 13, further comprising:
a sulfuric acid supply supplying sulfuric acid to the mixed fluid nozzle,
wherein the mixed fluid nozzle supplies, onto the front surface of the substrate, the fluid containing the vapor or mist of the pure water, the hydrogen peroxide solution, and/or a sulfuric acid hydrogen peroxide mixture (SPM), which is a mixture of the hydrogen peroxide solution and the sulfuric acid, and
the control circuitry is configured to control the operation of the substrate processing apparatus to further perform, after the third process, a fourth process of discharging a mixed fluid of the SPM and the vapor or mist of the pure water onto the front surface of the substrate.

15. The substrate processing apparatus of claim 14,
wherein the mixed fluid nozzle is a bar nozzle having multiple discharge openings, and when a lengthwise direction of the bar nozzle is aligned with a radial direction of the substrate, the multiple discharge openings are arranged in the radial direction of the substrate.

16. The substrate processing apparatus of claim 15, further comprising:
a hydrogen peroxide solution supply line supplying the hydrogen peroxide solution from a hydrogen peroxide solution source;
a sulfuric acid supply line supplying the sulfuric acid from a sulfuric acid source; and
a chemical liquid supply line supplying a liquid from a mixer where the hydrogen peroxide solution supply line and the sulfuric acid supply line converge to the mixed fluid nozzle,
wherein the transition from the third process to the fourth process is carried out by supplying the sulfuric acid from the sulfuric acid source to the mixer via the sulfuric acid supply line while continuing a state in which the fluid containing the vapor or mist of the pure water is supplied from the pure water vapor supply to the mixed fluid nozzle and the hydrogen peroxide solution is supplied from the hydrogen peroxide solution source to the mixed fluid nozzle via the hydrogen peroxide solution supply line, the mixer, and the chemical liquid supply line, to mix the hydrogen peroxide solution and the sulfuric acid in the mixer to produce the SPM.

17. A non-transitory computer-readable recording medium having stored thereon a program that, when executed by control circuitry of a substrate processing apparatus comprising a computer, causes the substrate processing apparatus to perform a substrate processing method as follows:
discharging a processing liquid containing hydrofluoric acid onto a front surface of a substrate;
discharging, after the discharging of the processing liquid, a rinse liquid onto the front surface of the substrate; and
discharging, after the discharging of the rinse liquid, a mixed fluid of hydrogen peroxide solution and vapor or mist of pure water onto the front surface of the substrate.

18. The non-transitory computer-readable recording medium of claim 17, wherein the method further comprises:
supplying a heated temperature control fluid to a rear surface of the substrate during the discharging of the mixed fluid of the hydrogen peroxide solution and vapor or mist of pure water to heat the substrate.

19. The non-transitory computer-readable recording medium of claim 17,
wherein the discharging of the mixed fluid of the hydrogen peroxide solution and vapor or mist of pure water is started before the discharging of the rinse liquid is completed, and when the discharging of the mixed fluid of the hydrogen peroxide solution and vapor or mist of pure water is started, a landing point of the rinse liquid being supplied onto the front surface of the substrate in the discharging of the rinse liquid is moved toward a periphery of the substrate and then away from the substrate.

20. The non-transitory computer-readable recording medium of claim 17, wherein the method further comprises:
discharging, after the discharging of the mixed fluid of the hydrogen peroxide solution and vapor or mist of pure water, a mixed fluid of a sulfuric acid hydrogen peroxide mixture (SPM), which is a mixture of sulfuric acid and hydrogen peroxide solution, and vapor or mist of pure water onto the front surface of the substrate.
